(19) United States
(12) Patent Application Publication
(10) Pub. No.: US 2026/0371830 A1
(43) Pub. Date: Nov. 19, 2026

(54) DETECTION DEVICE AND METHOD FOR MANUFACTURING DETECTION DEVICE

(71) Applicant: Japan Display Inc., Tokyo (JP)

(72) Inventors: Kazuhide MOCHIZUKI, Tokyo (JP); Kento HIMOTO, Tokyo (JP); Gen KOIDE, Tokyo (JP)

(21) Appl. No.: 19/411,621

(22) Filed: Dec. 8, 2025

Related U.S. Application Data
(63) Continuation of application No. PCT/JP2024/017755, filed on May 14, 2024.

(30) Foreign Application Priority Data
Jun. 20, 2023 (JP) 2023-100536

(51) Int. Cl. H10K 39/32; H10K 39/38; H10K 71/00; H10K 71/60

(52) U.S. Cl. CPC H10K 39/32; H10K 39/38; H10K 71/60; H10K 71/621

(57) ABSTRACT

According to an aspect, a detection device includes: a substrate; an organic insulating film and a barrier film staked on the substrate; an organic optical sensor in which a lower electrode, a lower buffer layer, an active layer, an upper buffer layer, and an upper electrode are stacked on the barrier film in a detection area of the substrate in the order listed; and a sealing film that covers the organic optical sensor. Side surfaces of the lower buffer layer, the active layer, and the upper buffer layer are covered by the upper electrode. The upper electrode is covered by the sealing film.

### CROSS-REFERENCE TO RELATED APPLICATION

This application claims the benefit of priority from Japanese Patent Application No. 2023-100536 filed on Jun. 20, 2023 and International Patent Application No. PCT/JP 2024/017755 filed on May 14, 2024, the entire contents of which are incorporated herein by reference.

### BACKGROUND

### 1. Technical Field

What is disclosed herein relates to a detection device and a method for manufacturing the detection device.

### 2. Description of the Related Art

Optical sensors capable of detecting fingerprint patterns and vascular patterns are known (for example, Japanese Patent Application Laid-open Publication No. 2009-032005). Such optical sensors each include a plurality of photodiodes (organic photodiodes (OPDs)) each using an organic semiconductor material as an active layer. As described in International Patent Application Publication No. WO 2020/188959, in each of the photodiodes, for example, a lower electrode, an electron transport layer, the active layer, a hole transport layer, and an upper electrode are stacked in this order. The electron transport layer and the hole transport layer are each also called a buffer layer.

In a manufacturing process of a detection device including the OPDs, a patterning mask may come into contact with film surfaces of the active layer and the like in a film forming process using a patterning mask. Occurrence of scratches or attachment of foreign matter on the film surfaces of the active layer and the like cause film thickness variations or shape variations on outer edge sides of the OPDs. These film thickness variations or shape variations may change conditions of light incident on an organic optical sensor, which may reduce detection accuracy.

Technologies related to masks used for forming conductive films and color filters of liquid crystal display devices are described in Japanese Patent Application Laid-open Publication No. 2002-038254 (JP-A-2002-038254), Japanese Patent Application Laid-open Publication No. 2005-120406 (JP-A-2005-120406), and Japanese Patent Application Laid-open Publication No. 2005-068501 (JP-A-2005-068501). However, JP-A-2002-038254, JP-A-2005-120406, and JP-A-2005-068501 do not describe a detection device using the OPDs and a method for manufacturing the detection device.

For the foregoing reasons, there is a need for a detection device and a method for manufacturing the detection device capable of reducing the occurrence of scratches and attachment of foreign matter on the organic optical sensor.

### SUMMARY

According to an aspect, a detection device includes: a substrate; an organic insulating film and a barrier film staked on the substrate; an organic optical sensor in which a lower electrode, a lower buffer layer, an active layer, an upper buffer layer, and an upper electrode are stacked on the barrier film in a detection area of the substrate in the order listed; and a sealing film that covers the organic optical sensor. Side surfaces of the lower buffer layer, the active layer, and the upper buffer layer are covered by the upper electrode. The upper electrode is covered by the sealing film.

According to an aspect, a method for manufacturing a detection device includes: forming an organic insulating film, a barrier film, a lower electrode, a lower buffer layer, an active layer, and an upper buffer layer on a substrate in the order listed; forming an upper metal layer on the upper buffer layer in an area corresponding to a detection area of the substrate using a first patterning mask, and removing the lower buffer layer, the active layer, and the upper buffer layer in an area in which the upper metal layer is not provided; and forming an upper electrode on the upper metal layer using a second patterning mask. In the forming the upper electrode, a distance between an inner wall of an opening of the second patterning mask and a side surface of the active layer is 500 μm or more. Side surfaces of the lower buffer layer, the active layer, and the upper buffer layer are covered by the upper electrode.

According to an aspect, a method for manufacturing a detection device includes: forming an organic insulating film, a barrier film, a lower electrode, a lower buffer layer, an active layer, and an upper buffer layer on a substrate in the order listed; forming an upper metal layer on the upper buffer layer in an area corresponding to a detection area of the substrate using a first patterning mask, and removing the lower buffer layer, the active layer, and the upper buffer layer in an area in which the upper metal layer is not provided; and forming an upper electrode on the upper metal layer using a second patterning mask. In the forming the upper electrode, the second patterning mask is supported by a spacer provided on an outer edge side of the substrate. Side surfaces of the lower buffer layer, the active layer, and the upper buffer layer are covered by the upper electrode.

### BRIEF DESCRIPTION OF THE DRAWINGS

FIG. 1 is a plan view schematically illustrating a detection device according to a first embodiment;

FIG. 2 is a block diagram illustrating a configuration example of the detection device according to the first embodiment;

FIG. 3 is a circuit diagram illustrating the detection device according to the first embodiment;

FIG. 4 is a plan view schematically illustrating a configuration of lower electrodes, a lower buffer layer, an active layer, an upper buffer layer, and an upper electrode included in a plurality of photodiodes;

FIG. 5 is a sectional view taken along V-V′ in FIG. 4;

FIG. 6 is a sectional view taken along VI-VI′ in FIG. 4;

FIG. 7 is an explanatory diagram schematically illustrating a manufacturing process of the detection device according to the first embodiment;

FIG. 8 is a magnified explanatory diagram of processes at Step ST1 and Step ST2 in FIG. 7; and

FIG. 9 is an explanatory diagram schematically illustrating a manufacturing process of the detection device according to a second embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

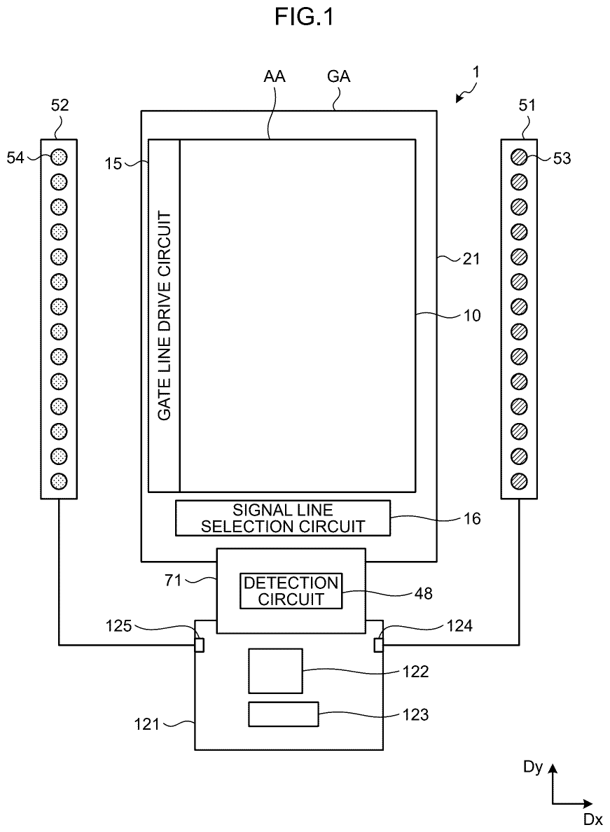

FIG. 1 is a plan view schematically illustrating a detection device according to a first embodiment. As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

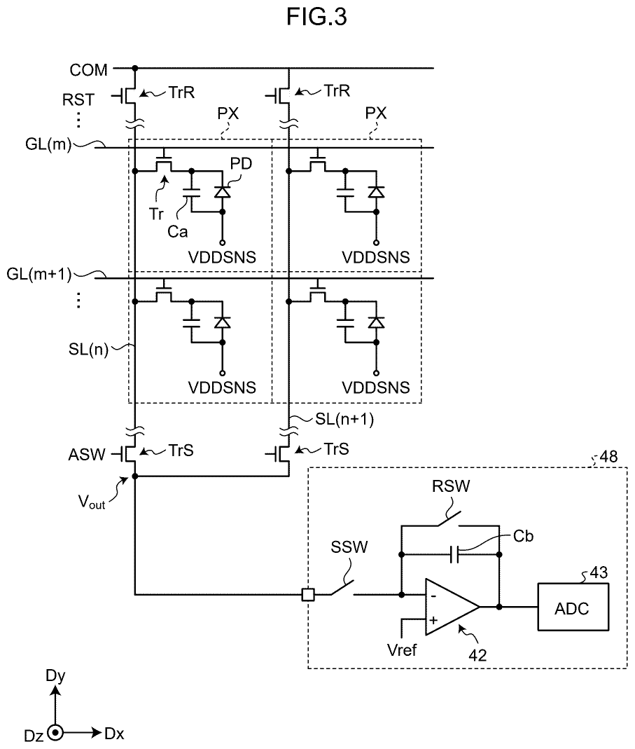

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

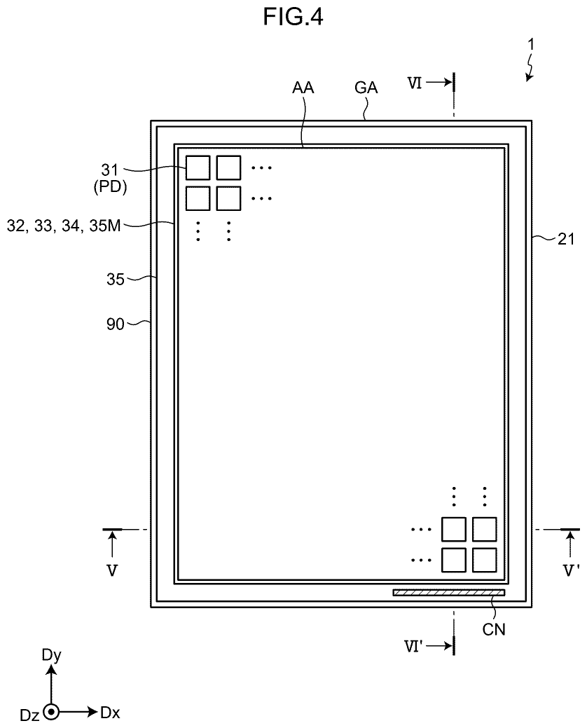

The substrate 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and the outer edges of the substrate 21, and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA and is provided between the sensor 10 and the detection circuit 48.

In the following description, the first direction Dx is one direction in a plane parallel to the substrate 21. The second direction Dy is one direction in the plane parallel to the substrate 21 and is a direction orthogonal to the first direction Dx. The second direction Dy may, however, non-orthogonally intersect the first direction Dx. A third direction Dz is a direction orthogonal to the first direction Dx and the second direction Dy and is a direction normal to a principal surface of the substrate 21. The term “plan view” refers to a positional relation when viewed from a direction orthogonal to the substrate 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled to the control circuit 122 and the power supply circuit 123 through respective terminals 124 and 125 provided on the control substrate 121.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect the fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

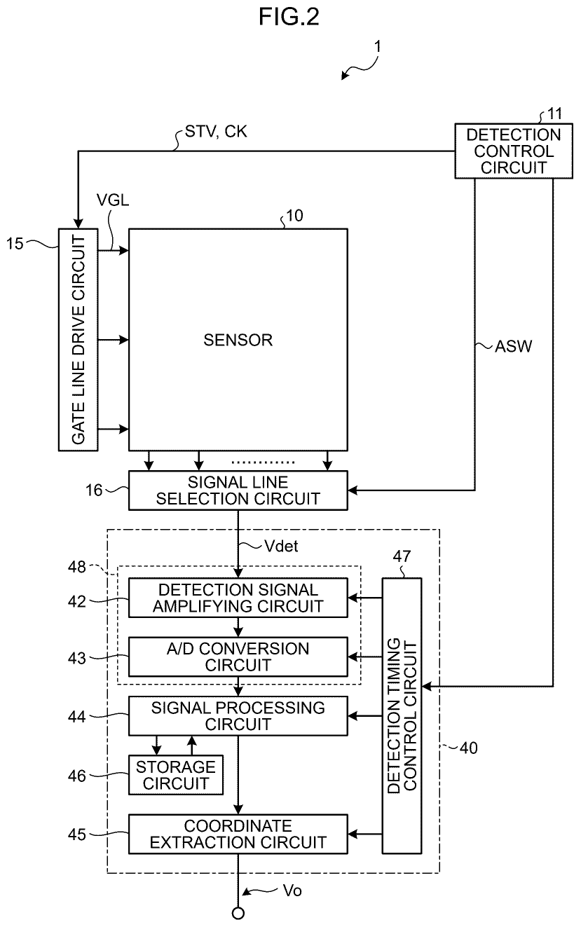

FIG. 2 is a block diagram illustrating a configuration example of the detection device according to the embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light irradiating the photodiode PD as a detection signal Vdet to the signal line selection circuit 16. The sensor 10 performs the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 is a circuit that drives a plurality of gate lines GL (refer to FIG. 3) based on the various control signals. The gate line drive circuit 15 sequentially or simultaneously selects the gate lines GL, and supplies the gate drive signals VGL to the selected gate lines GL. Through this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signal Vdet of the photodiode PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate these circuits synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL(m) and GL(m+1) arranged in the second direction Dy among the gate lines GL. FIG. 3 also illustrates two signal lines SL(n) and SL(n+1) arranged in the first direction Dx among the signal lines SL. The sensor pixel PX is an area surrounded by the gate lines GL and the signal lines SL.

The drive transistors Tr are provided correspondingly to the photodiodes PD. Each of the drive transistors Tr is configured as a thin-film transistor, and in this example, configured as an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The others of the sources and the drains of the drive transistors Tr are each coupled to the cathode of the photodiode PD and the capacitive element Ca.

The anode of the photodiode PD is supplied with the sensor power supply signal VDDSNS from the power supply circuit 123 (refer to FIG. 1). The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the amount of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 via an output transistor TrS of the signal line selection circuit 16. Thus, the detection device 1 can detect a signal corresponding to the amount of the light irradiating the photodiode PD for each sensor pixel PX.

In the readout period, a switch SSW is turned on to couple the detection circuit 48 to the signal line SL. The detection signal amplifying circuit 42 of the detection circuit 48 converts a current or an electric charge supplied from the signal line SL into a voltage corresponding thereto. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the embodiment, the same signal as the sensor reference voltage COM is supplied as the reference potential (Vref) voltage. The control circuit 122 (refer to FIG. 1) calculates the difference between the detection signal Vdet when light irradiates the photodiode PD and the detection signal Vdet when light does not irradiate the photodiode PD as each of the sensor output voltages Vo. The detection signal amplifying circuit 42 includes a capacitive element Cb and a reset switch RSW. In a reset period, the reset switch RSW is turned on to reset the electric charge of the capacitive element Cb.

The drive transistor Tr is not limited to the n-type TFT and may be configured as a p-type TFT. The pixel circuit of the sensor pixel PX illustrated in FIG. 3 is merely exemplary. The sensor pixel PX may be provided with a plurality of transistors corresponding to one photodiode PD.

The following describes a detailed configuration of the photodiodes PD with reference to FIGS. 4 to 6. FIG. 4 is a plan view schematically illustrating a configuration of lower electrodes, a lower buffer layer, an active layer, an upper buffer layer, and an upper electrode included in the photodiodes.

As illustrated in FIG. 4, the photodiodes PD (organic optical sensors) are arranged in a matrix having a row-column configuration in the detection area AA. The photodiodes PD each include a lower electrode 31, a lower buffer layer 32, an active layer 33, an upper buffer layer 34, and an upper metal layer 35M, and an upper electrode 35. A plurality of the lower electrodes 31 are provided so as to be separated for each of the photodiodes PD, and arranged in a matrix having a row-column configuration in the detection area AA. The lower buffer layer 32, the active layer 33, the upper buffer layer 34, and the upper metal layer 35M are continuously provided across the photodiodes PD, and are provided over the entire detection area AA.

An upper electrode 35 is continuously provided across the photodiodes PD and is provided in the detection area AA and the peripheral area GA. The upper electrode 35 is provided so as to cover the lower buffer layer 32, the active layer 33, the upper buffer layer 34, and the upper metal layer 35M. The outer edge of the upper electrode 35 is located outside the lower buffer layer 32, the active layer 33, the upper buffer layer 34, and the upper metal layer 35M (closer to the outer edge of the substrate 21 than these layers). A portion of the upper electrode 35 is coupled to a contact CN provided in the peripheral area GA and is electrically coupled to external circuits (such as the control circuit 122 and the power supply circuit 123 (refer to FIG. 1)) via wiring of the substrate 21.

The detection device 1 includes a sealing film 90 covering the photodiodes PD. The sealing film 90 is provided across the detection area AA and the peripheral area GA and extends to the outer edge side of the substrate 21. The sealing film 90 is provided so as to cover the photodiodes PD. The outer edge of the sealing film 90 is located outside the outer edge of the upper electrode 35 (located further toward the outer edge of the substrate 21 than the outer edge of the upper electrode 35).

Although FIG. 4 does not illustrate the wiring substrate 71 (refer to FIG. 1), the wiring substrate 71 is coupled to terminals provided on the substrate 21 outside the upper electrode 35. The sealing film 90 may be provided with openings at coupling points between the wiring substrate 71 and the terminals.

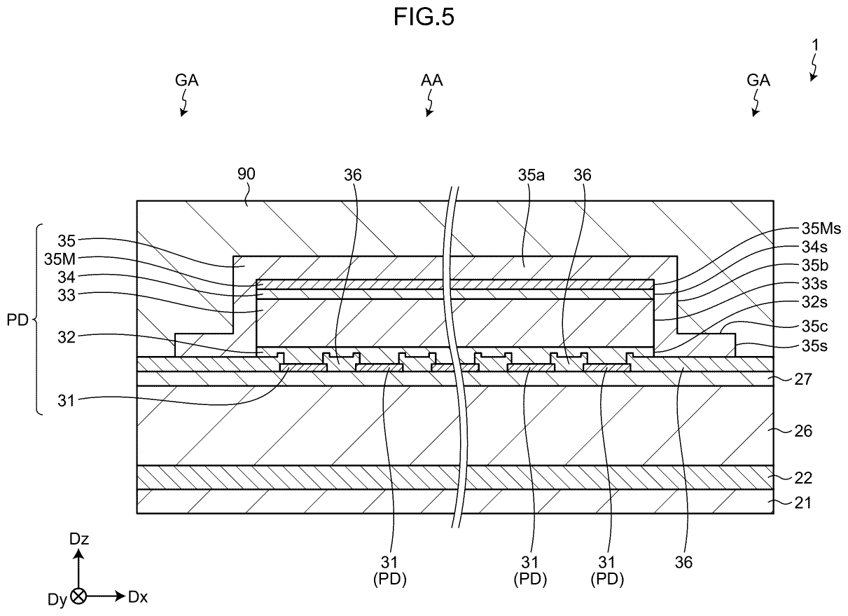

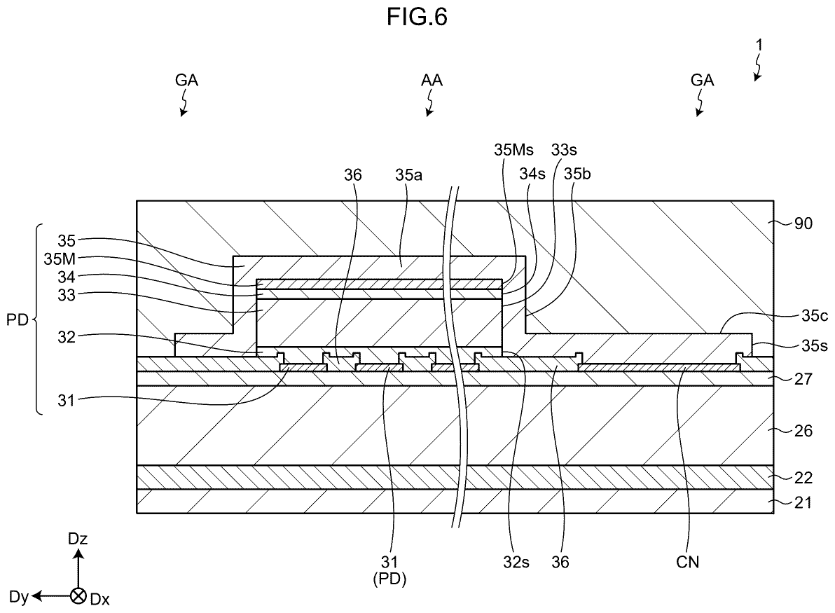

The following describes a multilayered structure of the photodiodes PD and the sealing film 90 of the detection device 1. FIG. 5 is a sectional view taken along V-V′ in FIG. 4. FIG. 6 is a sectional view taken along VI-VI′ in FIG. 4.

In the following description, a direction from the substrate 21 toward the sealing film 90 in a direction orthogonal to a surface of the substrate 21 is referred to as “upper side” or simply “above”. A direction from the sealing film 90 toward the substrate 21 is referred to as “lower side” or simply “below”.

As illustrated in FIGS. 5 and 6, the detection device 1 includes the substrate 21, a TFT layer 22, an organic insulating film 26, a barrier film 27, the photodiode PD, and the sealing film 90. The TFT layer 22, the organic insulating film 26, the barrier film 27, the photodiode PD, and the sealing film 90 are stacked in the detection area AA on the substrate 21 in this order.

The substrate 21 is an insulating substrate formed of a film-like resin. The TFT layer 22 is a circuit-forming layer in which the pixel circuits included in the sensor pixels PX (refer to FIG. 3) are formed. The TFT layer 22 includes the drive transistors Tr, various types of wiring such as the gate lines GL and the signal lines SL, and a plurality of inorganic insulating films that insulate between layers.

The organic insulating film 26 is provided so as to cover the drive transistors Tr formed in the TFT layer 22. The organic insulating film 26 is a planarizing film formed of an organic insulating material. The barrier film 27 is provided on the organic insulating film 26. The barrier film 27 is formed, for example, of an inorganic insulating material such as a silicon nitride (SiN) film.

Each of the photodiodes PD is provided on the barrier film 27. In the photodiode PD, the lower electrode 31, the lower buffer layer 32, the active layer 33, the upper buffer layer 34, the upper metal layer 35M, and the upper electrode 35 are stacked in the direction orthogonal to the substrate 21 in this order. The photodiode PD of the present embodiment is an organic photodiode (OPD) using an organic semiconductor as the active layer 33.

The lower electrode 31 is formed, for example, of a light-transmitting conductive material such as indium tin oxide (ITO). The lower buffer layer 32, the active layer 33, the upper buffer layer 34, the upper metal layer 35M, and the upper electrode 35 are provided continuously across the photodiodes PD. Specifically, the lower buffer layer 32, the active layer 33, the upper buffer layer 34, the upper metal layer 35M, and the upper electrode 35 are provided so as to overlap the lower electrodes 31, and are also provided in areas between the adjacent lower electrodes 31.

An insulating film 36 is provided so as to cover the periphery of the lower electrodes 31. The insulating film 36 insulates between the lower electrodes 31 of the adjacent photodiodes PD. Even if a step break occurs in the lower buffer layer 32 at the periphery of the lower electrode 31, the occurrence of a short circuit between the active layer 33 and the lower electrode 31 can be prevented or reduced because the insulating film 36 is provided. In the present embodiment, the insulating film 36 is formed of an inorganic insulating material, such as a silicon nitride (SiN) film or a silicon oxide (SiO₂) film. The insulating film 36 is provided so as to cover the periphery of the contact CN. The insulating film 36 is provided so as to cover the entire barrier film 27, but is not limited thereto, and only needs to be provided so as to cover at least the periphery of the lower electrodes 31 and the periphery of the contact CN.

The active layer 33 changes in characteristics (for example, voltage-current characteristics and resistance value) depending on light emitted thereto. An organic material is used as a material of the active layer 33. Specifically, the active layer 33 has a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the active layer 33, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 33 can be formed by a vapor deposition process (dry process) using any of the low-molecular-weight organic materials listed above. In this case, the active layer 33 may be, for example, a multilayered film of CuPc and F₁₆CuPc, or a multilayered film of rubrene and C₆₀. The active layer 33 can also be formed by a coating process (wet process). In this case, the active layer 33 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 33 can be a film made of a mixture of P3HT and PCBM, or a film made of a mixture of F8BT and PDI. The active layer 33 is not limited to the bulk heterostructure and may have a positive-intrinsic-negative (PIN) structure.

The lower buffer layer 32 and the upper buffer layer 34 are provided to facilitate holes and electrons generated in the active layer 33 to reach the lower electrode 31 or the upper electrode 35. The lower buffer layer 32 is provided between the lower electrode 31 and the active layer 33 and is in direct contact with the lower electrode 31 and the active layer 33. The lower buffer layer 32 is provided between the adjacent lower electrodes 31 so as to cover the barrier film 27 and the insulating film 36.

The upper buffer layer 34 is provided between the active layer 33 and the upper electrode 35. The upper metal layer 35M is provided between the upper buffer layer 34 and the upper electrode 35. The upper buffer layer 34 is in direct contact with the active layer 33 and the upper metal layer 35M.

In the present embodiment, the lower electrode 31 is a cathode electrode of the photodiode PD, and the upper electrode 35 is an anode electrode of the photodiode PD. In this case, the lower buffer layer 32 is an electron transport layer and the upper buffer layer 34 is a hole transport layer. Polyethylenimine ethoxylated (PEIE) is used as a material of the electron transport layer. The material of the hole transport layer is a metal oxide layer. Tungsten oxide (WO₃), molybdenum oxide, or the like is used as the oxide metal layer.

The lower electrode 31 may be the anode electrode of the photodiode PD, and the upper electrode 35 may be the cathode electrode of the photodiode PD. In that case, the lower buffer layer 32 may be a hole transport layer, and the upper buffer layer 34 may be an electron transport layer.

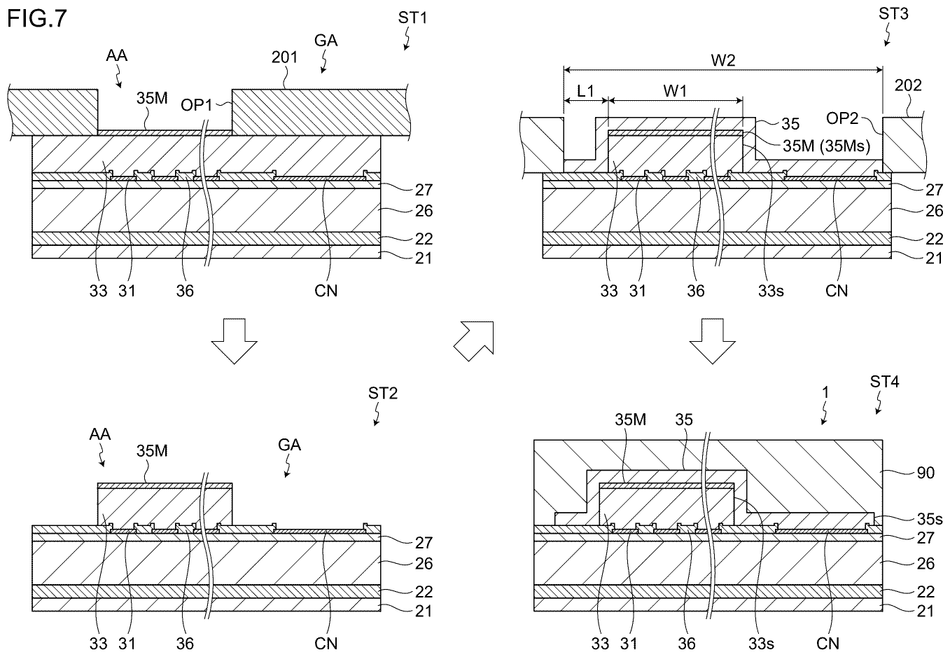

The upper metal layer 35M is formed with the same width (area) as the lower buffer layer 32, the active layer 33, and the upper buffer layer 34. The upper metal layer 35M has both a function as an upper electrode of the photodiode PD and a function as a mask when patterning the lower buffer layer 32, the active layer 33, and the upper buffer layer 34. A manufacturing process of the photodiode PD will be described later with reference to FIG. 7.

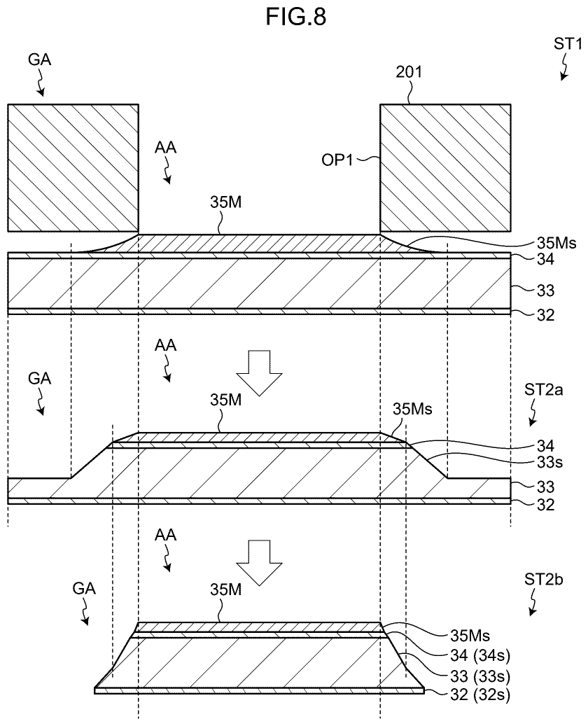

In FIGS. 5 and 6, side surfaces of the photodiode PD (side surfaces 32s, 33s, 34s, and 35Ms of the lower buffer layer 32, the active layer 33, the upper buffer layer 34, and the upper metal layer 35M) are schematically illustrated orthogonally to the surface of the substrate 21. In reality, however, the side surfaces 32s, 33s, 34s, and 35Ms of the photodiode PD each have a forward tapered shape (refer to a magnified view in FIG. 8).

The upper electrode 35 covers the upper surface of the upper metal layer 35M, and also covers the side surface 32s of the lower buffer layer 32, the side surface 33s of the active layer 33, the side surface 34s of the upper buffer layer 34, and the side surface 35Ms of the upper metal layer 35M. In the following description, “the side surface 32s of the lower buffer layer 32, the side surface 33s of the active layer 33, the side surface 34s of the upper buffer layer 34, and the side surface 35Ms of the upper metal layer 35M” may be referred to as “the side surfaces 32s, 33s, 34s, and 35Ms of the photodiode PD”.

More specifically, the upper electrode 35 includes an overlay portion 35a, a side portion 35b, and an extended portion 35c. The overlay portion 35a covers the upper surface of the upper metal layer 35M. The side portion 35b covers the side surfaces 32s, 33s, 34s, and 35Ms of the photodiode PD. The upper end of the side portion 35b is coupled to the overlay portion 35a, and the lower end of the side portion 35b is coupled to the extended portion 35c. The extended portion 35c extends to the peripheral area GA outside the side surfaces 32s, 33s, 34s, and 35Ms of the photodiode PD. The extended portion 35c of the upper electrode 35 is provided on the barrier film 27 and the insulating film 36 in an area not overlapping the photodiodes PD.

A side surface 35s on the outer edge side of the upper electrode 35 (side surface 35s of the extended portion 35c) is located closer to the outer edge of the substrate 21 than the side surfaces 32s, 33s, 34s, and 35Ms of the photodiode PD are. In other words, the planar area of the upper electrode 35 is larger than the planar area of each of the lower buffer layer 32, the active layer 33, the upper buffer layer 34, and the upper metal layer 35M. On the outer edge side of the substrate 21, the side surface 35s of the upper electrode 35 is located closer to the detection area AA than the side surface of the barrier film 27 is. As illustrated in FIG. 6, a portion of the extended portion 35c of the upper electrode 35 extends to an area overlapping the contact CN and is coupled to the contact CN.

The upper electrode 35 is formed, for example, of a light-transmitting conductive material such as ITO or indium zinc oxide (IZO). The upper electrode 35 is not limited thereto, and may be formed, for example, of a non-light-transmitting conductive material such as silver (Ag). The upper metal layer 35M is formed of a metal material such as silver (Ag). That is, the upper metal layer 35M may be the same metal material as the upper electrode 35.

The sealing film 90 is provided so as to cover the photodiodes PD. The sealing film 90 is provided so as to cover the overlay portion 35a, the side portion 35b, and the extended portion 35c of the upper electrode 35. A side surface of the sealing film 90 is located closer to the outer edge of the substrate 21 than the side surface 35s on the outer edge side of the upper electrode 35 is. The sealing film 90 well seals the photodiode PD, and thus can reduce or prevent the entry of external moisture into the photodiode PD. Since the sealing film 90 covers the side surface 35s on the outer edge side of the upper electrode 35, the entry of moisture from the outer edge side of the substrate 21 can be prevented or reduced more effectively than a case where the upper electrode 35 extends to the outer edge side of the substrate 21.

The sealing film 90 is formed of an inorganic film such as a silicon nitride film or an aluminum oxide film. The sealing film 90 is not limited to a single-layer film and may be a multilayered film in which a plurality of inorganic films are stacked. Alternatively, the sealing film 90 may be a multilayered film in which an organic film formed of a resin film such as an acrylic film and an inorganic film are stacked.

As described above, in the detection device 1 of the present embodiment, the side surfaces 32s, 33s, 34s, and 35 Ms of the lower buffer layer 32, the active layer 33, the upper buffer layer 34, and the upper metal layer 35M are covered by the upper electrode 35. This configuration can prevent or reduce contact between a patterning mask and the active layer 33 when forming the upper electrode 35, compared with a case where the upper electrode 35 is formed in the same shape as the lower buffer layer 32, the active layer 33, and the upper buffer layer 34.

### Method for Manufacturing Detection Device

The following describes a method for manufacturing the detection device 1 of the present embodiment, with reference to FIG. 7. FIG. 7 is an explanatory diagram schematically illustrating the manufacturing process of the detection device according to the first embodiment. FIG. 8 is a magnified explanatory diagram of processes at Step ST1 and Step ST2 in FIG. 7. To facilitate viewing of the figure, FIG. 7 does not illustrate the lower buffer layer 32 and the upper buffer layer 34.

As illustrated in FIG. 7, the TFT layer 22, the organic insulating film 26, and the barrier film 27 are formed on the substrate 21. The lower electrodes 31, the insulating film 36, the lower buffer layer 32 (refer to FIG. 8), the active layer 33, and the upper buffer layer 34 (refer to FIG. 8) that are included in the photodiode PD are formed on the barrier film 27 in this order. The lower electrodes 31 are patterned in a matrix having a row-column configuration corresponding to the arrangement of the photodiodes PD. The lower buffer layer 32, the active layer 33, and the upper buffer layer 34 are formed over the entire surface of the substrate 21 across the detection area AA and peripheral area GA.

Then, a film forming device (not illustrate) forms the upper metal layer 35M on the upper buffer layer 34 in an area corresponding to the detection area AA of the substrate 21 using a first patterning mask 201 (Step ST1). The first patterning mask 201 for forming the upper metal layer 35M is a metal mask having an opening OP1. The opening OP1 is provided in a position overlapping an area where the photodiodes PD are to be formed (detection area AA). The upper metal layer 35M is formed by sputtering, vapor deposition, plasma-enhanced chemical vapor deposition (CVD), or other methods.

As illustrated at Step ST1 of FIG. 8, in the film forming process of the upper metal layer 35M, the first patterning mask 201 is located away upward from the upper buffer layer 34. The upper metal layer 35M is formed so as to wrap around the outside of the opening OP1 of the first patterning mask 201. As a result, the side surface 35Ms of the upper metal layer 35M is formed into the forward tapered shape.

Then, as illustrated in FIG. 7, the lower buffer layer 32, the active layer 33, and the upper buffer layer 34 are removed from an area where the upper metal layer 35M is not provided (Step ST2). The upper metal layer 35M is used as a mask in the removal process at Step ST2. The lower buffer layer 32, the active layer 33, and the upper buffer layer 34 in the area not overlapping the upper metal layer 35M are removed by dry etching. In other words, the lower buffer layer 32, the active layer 33, and the upper buffer layer 34 in areas overlapping the upper metal layer 35M are formed as the photodiodes PD.

As illustrated at Step ST2a in FIG. 8, in the removal process of the lower buffer layer 32, the active layer 33, and the upper buffer layer 34, etching of the lower buffer layer 32, the active layer 33, and the upper buffer layer 34 first progresses in an area outside the side surface 35Ms of the upper metal layer 35M. At this time, a thinly formed outer edge portion of the upper metal layer 35M (portion overlapping the side surface 35Ms) is also etched together with the lower buffer layer 32, the active layer 33, and the upper buffer layer 34.

As illustrated at Step ST2b in FIG. 8, after the outer edge portion of the upper metal layer 35M is further removed, etching of the lower buffer layer 32, the active layer 33, and the upper buffer layer 34 sequentially progresses in an area overlapping the removed portion of the upper metal layer 35M. As a result, each of the side surfaces 32s, 33s, and 34s of the lower buffer layer 32, the active layer 33, and the upper buffer layer 34 of the photodiode PD is formed into a forward tapered shape. The side surface 35Ms of the upper metal layer 35M is also formed into a forward tapered shape.

Then, as illustrated in FIG. 7, the film forming device (not illustrated) forms the upper electrode 35 on the upper metal layer 35M using a second patterning mask 202 (Step ST3). The second patterning mask 202 for forming the upper electrode 35 is a metal mask having an opening OP2. The opening OP2 of the second patterning mask 202 has a width W2 that is larger than at least a width W1 of the active layer 33. The width W1 of the active layer 33 is the largest width between the side surfaces 33s of the active layer 33. Specifically, the active layer 33 has a forward tapered shape, and the maximum width W1 of the active layer 33 is a distance at the lower end of the side surface 33s of the active layer 33 in contact with the insulating film 36 or the barrier film 27.

A distance L1 between the inner wall of the opening OP2 of the second patterning mask 202 and the side surface 33 s of the active layer 33 is 500 μm or more. In more detail, the distance L1 is a distance between the inner wall of the opening OP2 of the second patterning mask 202 and a portion at the lower end of the side surface 33s of the active layer 33 in contact with the insulating film 36 or the barrier film 27, in a direction parallel to the surface of the substrate 21. The distance L1 varies for each side of the photodiode PD, depending on the positioning accuracy of the second patterning mask 202. For example, as illustrated in FIG. 7, at a portion where the contact CN is provided, the distance L1 between the inner wall of the opening OP2 and the side surface 33s of the active layer 33 is larger than the distance L1 on the opposite side. In the present embodiment, the second patterning mask 202 is located so that the smallest distance L1 along the outer edge of the photodiode PD is 500μm or more.

The width W2 of the opening OP2 is smaller than the width of the barrier film 27 formed on the substrate 21. The inner wall of the opening OP2 of the second patterning mask 202 overlaps the outer edge side of the barrier film 27 formed on the substrate 21.

As a result, the upper electrode 35 is formed so as to cover the upper surface of the upper metal layer 35M, the side surfaces 32s, 33s, and 34s of the photodiode PD, and the side surface 35 Ms of the upper metal layer 35M. The upper electrode 35 is provided so as to extend beyond the side surface 33s of the active layer 33 to the outer edge of the substrate 21. The side surface 35s on the outer edge side of the upper electrode 35 is formed on the inside (detection area AA side) of the side surface of the barrier film 27.

Then, the film forming device (not illustrated) forms the sealing film 90 so as to cover the upper electrode 35 (Step ST4). A patterning mask (not illustrated) for forming the sealing film 90 has an opening having a larger width than the opening OP2. As a result, the sealing film 90 is formed so as to cover the entire surface of the upper electrode 35. The side surface 35s on the outer edge side of the upper electrode 35 is also covered by the sealing film 90. In other words, the side surface 35s on the outer edge side of the upper electrode 35 is formed on the inside (detection area AA side) of the side surface of the sealing film 90.

The detection device 1 of the present embodiment is formed by the processes described above. In the present embodiment, in the process to form the upper electrode 35 illustrated at Step ST3, the inner wall of the opening OP2 of the second patterning mask 202 is located at the predetermined distance L1 from the side surface 33s of the active layer 33. This configuration can prevent or reduce contact between the second patterning mask 202 and the side surface 33s of the active layer 33, compared with a case where the upper electrode 35 is formed in the same shape as the lower buffer layer 32, the active layer 33, and the upper buffer layer 34, that is, a case where the side surface 35s of the upper electrode 35 is provided in a position overlapping the side surfaces 32s, 33s, 34s, and 35Ms of the photodiode PD.

Even when each of the side surfaces 32s, 33s, and 34s of the lower buffer layer 32, the active layer 33, and the upper buffer layer 34 has a forward tapered shape as illustrated in FIG. 8, contact between the second patterning mask 202 and each of the side surfaces 32s, 33s, and 34s can be prevented or reduced. Therefore, in the present embodiment, the occurrence of scratches and attachment of foreign matter on the outer edge side of the photodiode PD can be prevented or reduced.

The method for manufacturing the detection device 1 illustrated in FIGS. 7 and 8 is merely an example, and can be changed as appropriate. For example, the multilayered structure and the forward tapered shape of each of the side surfaces 32s, 33s, and 34s illustrated in FIG. 8 are exaggerated for ease of understanding. The film thicknesses, and the slopes and widths of the side surfaces 32s, 33s, and 34s may be different.

### Second Embodiment

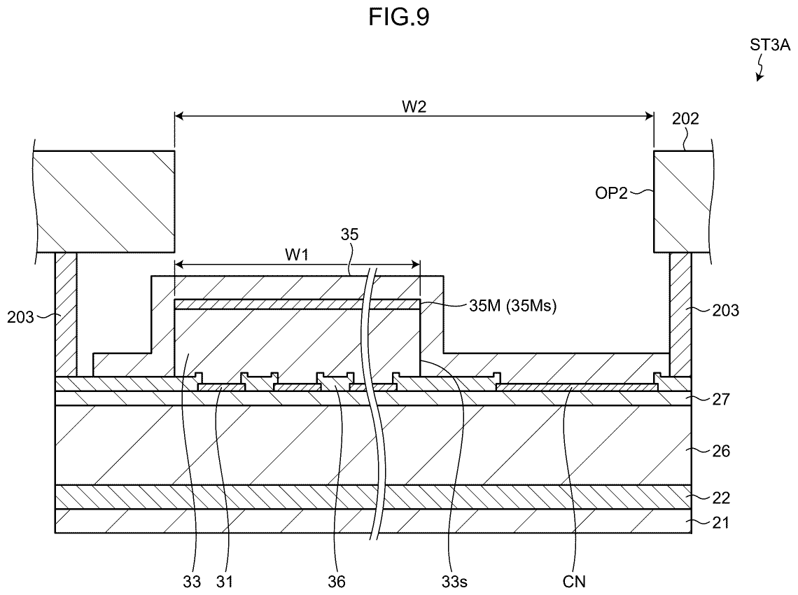

FIG. 9 is an explanatory diagram schematically illustrating a manufacturing process of the detection device according to a second embodiment. In the following description, the same components as those described in the embodiment above are denoted by the same reference numerals, and the description thereof will not be repeated. FIG. 9 does not illustrate the lower buffer layer 32 and the upper buffer layer 34 in the same way as FIG. 7.

The manufacturing process illustrated in FIG. 9 corresponds to the process to form the upper electrode 35 in FIG. 7 (Step ST3). In the second embodiment, the film forming process of the upper metal layer 35M, the removal of the active layer 33, and the film forming process of the sealing film 90 are the same as the processes at Steps ST1, ST2, and ST4 described above with reference to FIG. 7, and will not be described again.

As illustrated in FIG. 9, in the second embodiment, the second patterning mask 202 is supported by a spacer 203 provided on the outer edge side of the substrate 21. The height of the spacer 203 is larger than the total height of the lower buffer layer 32, the active layer 33, the upper buffer layer 34, and the upper metal layer 35M. The spacer 203 is resin tape formed of a resin material such as polyimide.

The second patterning mask 202 is located above the upper metal layer 35M. In more detail, the lower surface of the second patterning mask 202 is located away from the upper surface of the upper metal layer 35M in the direction orthogonal to the substrate 21. The width W2 of the opening OP2 of the second patterning mask 202 is larger than at least the width W1 of the active layer 33. However, in the present embodiment, the inner wall of the opening OP2 of the second patterning mask 202 may be located so as to overlap the side surface 33s of the active layer 33. That is, the distance L1 between the inner wall of the opening OP2 of the second patterning mask 202 and the side surface 33s of the active layer 33 (refer to FIG. 7) may be 500 μm or less.

The film forming device (not illustrated) forms the upper electrode 35 on the upper metal layer 35M using the second patterning mask 202 (Step ST3A). In the present embodiment, the upper electrode 35 is formed so as to wrap around between the lower surface of the second patterning mask 202 and the upper surface of the upper metal layer 35M. As a result, the upper electrode 35 is formed so as to cover the upper surface of the upper metal layer 35M, the side surfaces 32s, 33s, and 34s of the photodiode PD, and the side surface 35Ms of the upper metal layer 35M.

In the present embodiment, since the second patterning mask 202 is supported by the spacer 203 in the film forming process of the upper electrode 35, the contact between the second patterning mask 202 and each of the side surfaces 32s, 33s, and 34s of the lower buffer layer 32, the active layer 33, and the upper buffer layer 34 can be prevented or reduced.

While the preferred embodiments have been described above, the present invention is not limited to the embodiments described above. The content disclosed in the embodiments is merely an example, and can be variously modified within the scope not departing from the gist of the present invention. Any modifications appropriately made within the scope not departing from the gist of the present invention also naturally belong to the technical scope of the present invention. At least one of various omissions, substitutions, and changes of the components can be made without departing from the gist of the embodiments described above and the modifications thereof.

What is claimed is:

1. A detection device comprising:
a substrate;
an organic insulating film and a barrier film staked on the substrate;
an organic optical sensor in which a lower electrode, a lower buffer layer, an active layer, an upper buffer layer, and an upper electrode are stacked on the barrier film in a detection area of the substrate in the order listed; and
a sealing film that covers the organic optical sensor, wherein
side surfaces of the lower buffer layer, the active layer, and the upper buffer layer are covered by the upper electrode, and
the upper electrode is covered by the sealing film.

2. The detection device according to claim 1, wherein a side surface of the upper electrode is located closer to the detection area than a side surface of the barrier film is, on an outer edge side of the substrate.

3. The detection device according to claim 1, wherein a side surface of the organic optical sensor has a forward tapered shape.

4. The detection device according to claim 1, comprising an upper metal layer provided between the upper buffer layer and the upper electrode.

5. The detection device according to claim 4, wherein a side surface of the upper metal layer has a forward tapered shape.

6. A method for manufacturing a detection device, the method comprising:
forming an organic insulating film, a barrier film, a lower electrode, a lower buffer layer, an active layer, and an upper buffer layer on a substrate in the order listed;
forming an upper metal layer on the upper buffer layer in an area corresponding to a detection area of the substrate using a first patterning mask, and removing the lower buffer layer, the active layer, and the upper buffer layer in an area in which the upper metal layer is not provided; and
forming an upper electrode on the upper metal layer using a second patterning mask, wherein in the forming the upper electrode, a distance between an inner wall of an opening of the second patterning mask and a side surface of the active layer is 500 μm or more, and
side surfaces of the lower buffer layer, the active layer, and the upper buffer layer are covered by the upper electrode.

7. A method for manufacturing a detection device, the method comprising:
forming an organic insulating film, a barrier film, a lower electrode, a lower buffer layer, an active layer, and an upper buffer layer on a substrate in the order listed;
forming an upper metal layer on the upper buffer layer in an area corresponding to a detection area of the substrate using a first patterning mask, and removing the lower buffer layer, the active layer, and the upper buffer layer in an area in which the upper metal layer is not provided; and
forming an upper electrode on the upper metal layer using a second patterning mask, wherein
in the forming the upper electrode, the second patterning mask is supported by a spacer provided on an outer edge side of the substrate, and
side surfaces of the lower buffer layer, the active layer, and the upper buffer layer are covered by the upper electrode.
